(19) United States
(12) Patent Application Publication
(10) Pub. No.: US 2026/0333826 A1
(43) Pub. Date: Oct. 22, 2026

(54) FERROELECTRIC CAPACITOR AND METHOD FOR MANUFACTURING FERROELECTRIC CAPACITOR

(71) Applicant: JUSUNG ENGINEERING CO., LTD., Gwangju-si, Gyeonggi-do (KR)

(72) Inventors: Min Hyuk KIM, Yongin-si, Gyeonggi-do (KR); Chang Kyun PARK, Yongin-si, Gyeonggi-do (KR); Duck Ho KIM, Yongin-si, Gyeonggi-do (KR); Du Ho KIM, Yongin-si, Gyeonggi-do (KR); Kyung In MIN, Yongin-si, Gyeonggi-do (KR); Chul Joo HWANG, Yongin-si, Gyeonggi-do (KR)

(21) Appl. No.: 19/111,281

(22) PCT Filed: Sep. 12, 2023
(86) PCT No.: PCT/KR2023/013609

§ 371 Date: Mar. 12, 2025

(30) Foreign Application Priority Data
Sep. 15, 2022 (KR) 10-2022-0116446
Sep. 8, 2023 (KR) 10-2023-0119531

(51) Int. Cl. H10D 64/68; H10D 1/00; H10D 1/68; H10N 97/00

(52) U.S. Cl. CPC H10D 64/689; H10D 1/041; H10D 1/692; H10N 97/00

(57) ABSTRACT

The present invention relates to a ferroelectric capacitor and a method for manufacturing a ferroelectric capacitor, the ferroelectric capacitor comprising: a first electrode including titanium nitride (TiN); a ferroelectric layer formed on the first electrode and including a hafnium (Hf) oxide or a hafnium zirconium oxide (HZO); and an interface layer disposed between the ferroelectric layer and the first electrode.

### DESCRIPTION

### Technical Field

The present invention relates to a ferroelectric capacitor using a material having ferroelectricity and a method of manufacturing the ferroelectric capacitor.

### Background Art

Generally, a thin-film layer, a thin-film circuit pattern, or an optical pattern should be formed on a substrate for manufacturing a semiconductor device, a display device, a solar cell, etc. To this end, a processing process is performed on a substrate, and examples of the processing process include a deposition process of depositing a thin film including a specific material on the substrate, a photo process of selectively exposing a portion of a thin film by using a photosensitive material, an etching process of removing the selectively exposed portion of the thin film to form a pattern, etc.

A ferroelectric capacitor using ferroelectrics may be manufactured through the processing process. Ferroelectrics is a material having ferroelectricity where an internal electrical dipole moment is aligned when an electric field is not applied from the outside, and thus, spontaneous polarization is maintained.

Furthermore, in a ferroelectric capacitor using ferroelectrics, it is required to develop technology which may enhance the film quality of a ferroelectric layer formed by using ferroelectrics.

### DISCLOSURE

### Technical Problem

The present invention is devised to solve the above-described problem and is for providing a ferroelectric capacitor and a method of manufacturing the ferroelectric capacitor, which may enhance the film quality of a ferroelectric layer.

### Technical Solution

To accomplish the above-described objects, the present invention may include the following elements.

A ferroelectric capacitor according to the present invention may include: a first electrode including titanium nitride (TiN); a ferroelectric layer formed on the first electrode, the ferroelectric layer including hafnium (Hf) oxide or hafnium zirconium oxide (HZO); and an interface layer disposed between the ferroelectric layer and the first electrode.

In the ferroelectric capacitor according to the present invention, the interface layer may include titanium oxide and may be formed by performing treatment on the first electrode with ozone (O₃) or oxygen (O₂).

In the ferroelectric capacitor according to the present invention, the interface layer may include titanium dioxide (TiO₂).

A method of manufacturing a ferroelectric capacitor according to the present invention, a method of manufacturing a ferroelectric capacitor, may include: a step of preparing a substrate where a first electrode including titanium nitride (TiN) is formed; a step of performing treatment on the first electrode with ozone (O₃) or oxygen (O₂) to form an interface layer including titanium oxide on the first electrode; and a step of forming a ferroelectric layer including hafnium (Hf) oxide or hafnium zirconium oxide (HZO) on the interface layer.

A method of manufacturing a ferroelectric capacitor according to the present invention, a method of manufacturing a ferroelectric capacitor, may include: a step of preparing a substrate where a first electrode including titanium nitride (TiN) is formed; a step of forming an interface layer including titanium oxynitride (TiON) on the first electrode; and a step of forming a ferroelectric layer including hafnium (Hf) oxide or hafnium zirconium oxide (HZO) on the interface layer.

### Advantageous Effect

According to the present invention, the following effects may be realized.

The present invention may use an interface layer disposed between a first electrode and a ferroelectric layer, and thus, may prevent an oxygen vacancy from being formed in a process of forming the ferroelectric layer. Accordingly, the present invention may more reinforce the ferroelectricity of the ferroelectric layer and may increase a residual polarization value of the ferroelectric layer, and thus, may be implemented to enable driving with a lower voltage.

The present invention may be implemented to form a ferroelectric layer including hafnium zirconium oxide (HZO) by simultaneously supplying hafnium and zirconium. Accordingly, the present invention may enhance the film quality of the ferroelectric layer by using hafnium zirconium oxide. Also, the present invention may simultaneously supply hafnium and zirconium to form the ferroelectric layer, and thus, may contribute to shortening a process time for forming the ferroelectric layer.

### DESCRIPTION OF DRAWINGS

FIG. 1 is a schematic block diagram of an embodiment of a substrate processing apparatus for manufacturing a ferroelectric capacitor according to the present invention.

FIGS. 2 and 3 are schematic side cross-sectional views of an injection unit injecting a gas in an embodiment of a substrate processing apparatus for manufacturing a ferroelectric capacitor according to the present invention.

FIG. 4 is a schematic side cross-sectional view of a ferroelectric capacitor according to the present invention.

FIGS. 5 to 7 are schematic side cross-sectional views illustrating a process of manufacturing a ferroelectric capacitor according to the present invention.

FIGS. 8 to 10 are schematic flowcharts of a method of manufacturing a ferroelectric capacitor according to the present invention.

### MODE FOR INVENTION

Hereinafter, an embodiment of a ferroelectric capacitor according to the present invention will be described in detail with reference to the accompanying drawings. In describing an embodiment of the present invention, when an arbitrary structure is described as being formed “on” or “under” another structure, this description should be construed as including a case, where a third structure is disposed between the structures, as well as a case where the structures contact each other.

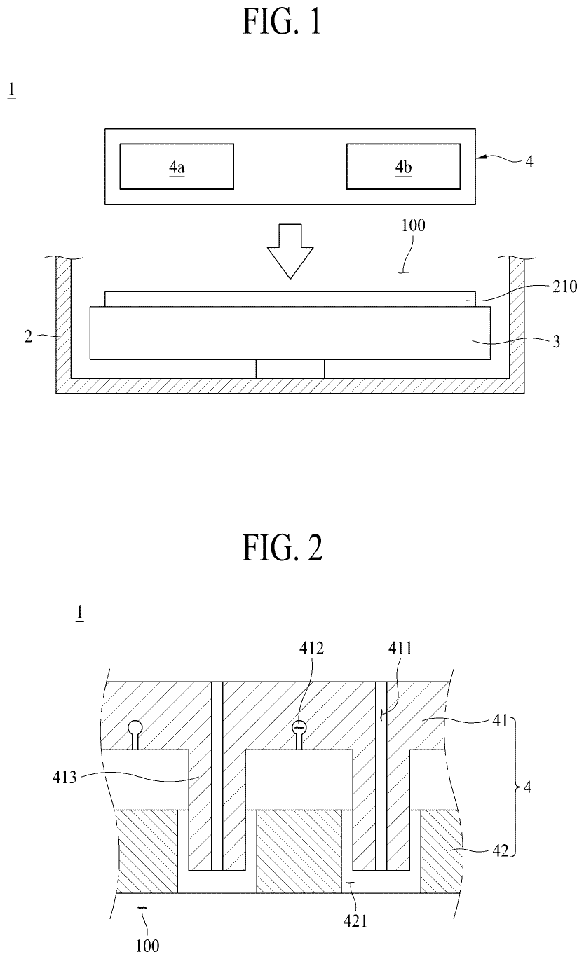

Referring to FIGS. 1 to 4, a ferroelectric capacitor 200 according to the present invention may be manufactured through a processing process on a substrate 210. The substrate 210 may be a silicon substrate, a glass substrate, a metal substrate, or the like. The ferroelectric capacitor 200 according to the present invention may be manufactured by using ferroelectrics having ferroelectricity.

The ferroelectric capacitor 200 according to the present invention may be manufactured through a processing process on a substrate processing apparatus 1. Before describing an embodiment of the ferroelectric capacitor 200 according to the present invention, an embodiment of the substrate processing apparatus 1 will be described below in detail.

The substrate processing apparatus 1 may include a chamber 2, a substrate supporting unit 3, and an injection unit 4.

Referring to FIGS. 1 to 3, the chamber 2 provides a processing space 100. A processing process on the substrate 210 may be performed in the processing space 100. The processing space 100 may be disposed in the chamber 2. An exhaust port (not shown) which exhausts a gas from the processing space 100 may be coupled to the chamber 2. The substrate supporting unit 3 and the injection unit 4 may be disposed in the chamber 2.

The substrate supporting unit 3 supports the substrate 210. The substrate supporting unit 3 may support one substrate 210, or may support a plurality of substrates 210. In a case where the plurality of substrates 210 are supported by the substrate supporting unit 3, a process of performing a processing process on the plurality of substrates 210 at a time to manufacture the ferroelectric capacitor 200 in each of the substrates 210 may be performed. The substrate supporting unit 3 may be coupled to the chamber 2. The substrate supporting unit 3 may be disposed in the chamber 2.

The injection unit 4 injects a gas toward the substrate supporting unit 3. The injection unit 4 may be connected with a supply unit (not shown). In this case, the injection unit 4 may inject a gas, supplied from the supply unit, toward the substrate supporting unit 3. The injection unit 4 may be disposed in the chamber 2. The injection unit 4 may be disposed to be opposite to the substrate supporting unit 3. The injection unit 4 may be disposed over the substrate supporting unit 3. The processing space 100 may be disposed between the injection unit 4 and the substrate supporting unit 3. The injection unit 4 may be coupled to a lid (not shown). The lid may be coupled to the chamber 2 to cover an upper portion of the chamber 2.

The injection unit 4 may include a first gas flow path 4a and a second gas flow path 4b.

The first gas flow path 4a is for injecting a first gas. One side of the first gas flow path 4a may be connected with the supply unit through a pipe, a hose, or the like. The other side of the first gas flow path 4a may communicate with the processing space 100. Accordingly, the first gas supplied from the supply unit may flow along the first gas flow path 4a, and then, may be injected into the processing space 100 through the first gas flow path 4a. The first gas flow path 4a may function as a flow path for enabling the first gas to flow and may function as an injection port for injecting the first gas into the processing space 100.

The second gas flow path 4b is for injecting a second gas. The second gas and the first gas may be different gases. For example, when the first gas is a source gas, the second gas may be a reactant gas. One side of the second gas flow path 4b may be connected with the supply unit through a pipe, a hose, or the like. The other side of the second gas flow path 4b may communicate with the processing space 100. Accordingly, the second gas supplied from the supply unit may flow along the second gas flow path 4b, and then, may be injected into the processing space 100 through the second gas flow path 4b. The second gas flow path 4b may function as a flow path for enabling the second gas to flow and may function as an injection port for injecting the second gas into the processing space 100.

The second gas flow path 4b and the first gas flow path 4a may be disposed to be spatially separated from each other. Therefore, the second gas supplied from the supply unit to the second gas flow path 4b may be injected into the processing space 100 without passing through the first gas flow path 4a. The first gas supplied from the supply unit to the first gas flow path 4a may be injected into the processing space 100 without passing through the second gas flow path 4b. The second gas flow path 4b and the first gas flow path 4a may inject a gas toward different portions of the processing space 100.

For example, as illustrated in FIG. 2, the injection unit 4 may include a first plate 41 and a second plate 42.

The first plate 41 is disposed over the second plate 42. The first plate 41 and the second plate 42 may be disposed apart from each other. A plurality of first gas holes 411 may be formed in the first plate 41. Each of the first gas holes 411 may function as a path for enabling the first gas to flow. The first gas holes 411 may be included in the first gas flow path 4a. A plurality of second gas holes 412 may be formed in the second plate 42. Each of the second gas holes 412 may function as a path for enabling the second gas to flow. The second gas holes 412 may be included in the second gas flow path 4b. A plurality of protrusion members 413 may be coupled to the first plate 41. The protrusion members 413 may protrude toward the second plate 42 from a lower surface of the first plate 41. Each of the first gas holes 411 may be formed to pass through the first plate 41 and the protrusion member 413.

A plurality of openings 421 may be formed in the second plate 42. The openings 421 may be formed to pass through the second plate 42. The openings 421 may be disposed at position respectively corresponding to the protrusion members 413. Therefore, as illustrated in FIG. 2, the protrusion members 413 may be formed by a length which enables the protrusion members 413 to be respectively inserted into the openings 421. Although not shown, the protrusion members 413 may be formed by a length which enables the protrusion members 413 to be respectively disposed over the openings 421. The protrusion members 413 may be formed by a length which protrudes downward from the second plate 42. The second gas holes 412 may be disposed to inject a gas toward an upper surface of the second plate 42. Although not shown, a lower surface of the first plate 41 may be formed to be flat without the protrusion member 413.

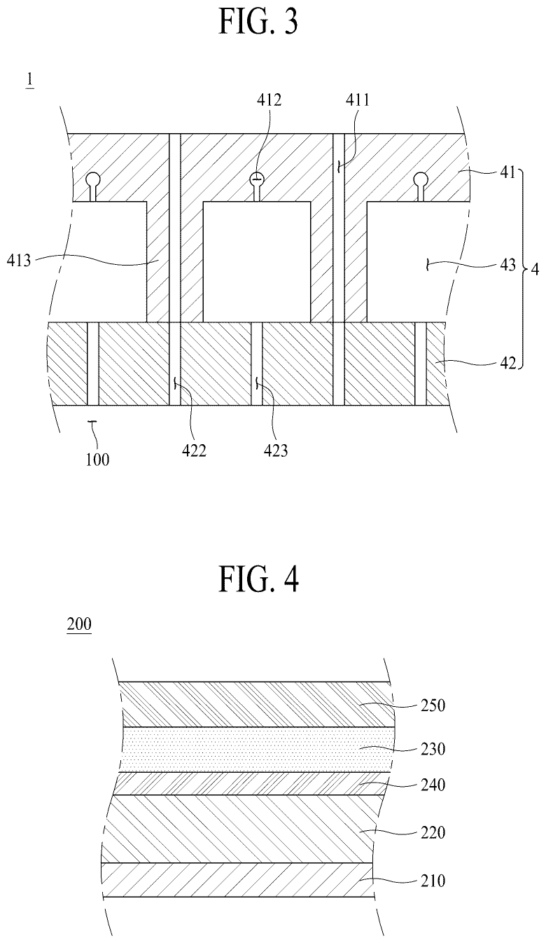

For example, as illustrated in FIG. 3, a plurality of first openings 422 and a plurality of second openings 423 may be formed in the second plate 42.

The first openings 422 may be formed to pass through the second plate 42. The first openings 422 may be respectively connected with the first gas holes 411. In this case, the protrusion members 413 may be disposed to contact an upper surface of the second plate 42. The first gas may be injected into the processing space 100 via the first gas holes 411 and the first openings 422. The first gas holes 411 and the first openings 422 may be included in the first gas flow path 4a.

The second openings 423 may be formed to pass through the second plate 42. The second openings 423 may be respectively connected with a buffer space 43 disposed between the first plate 41 and the second plate 42. The second gas may be injected into the processing space 100 via the second gas holes 412, the buffer space 43, and the second openings 423. The second gas holes 412, the buffer space 43, and the second openings 423 may be included in the second gas flow path 4b.

Although not shown, in a case where the lower surface of the first plate 41 is formed to be flat without the protrusion member 413, each of the first gas and the second gas may be supplied to a space between the first plate 41 and the second plate 42 through the first gas holes 411 and the second gas holes 412, and then, may be injected into the processing space 100 through the first gas holes 411 and the second gas holes 412. In this case, when the supply of the first gas through the first gas holes 411 and the supply of the second gas through the second gas holes 412 are simultaneously performed, the first gas and the second gas may be mixed in the space between the first plate 41 and the second plate 42, and then, may be injected into the processing space 100 through the first openings 422 and the second openings 423.

Furthermore, the first openings 422 may be respectively disposed vertically under the first gas holes 411. In this case, the first opening 422 and the first gas holes 411 may be disposed on the same vertical line. Although not shown, the first opening 422 and the first gas holes 411 may be disposed at staggered positions. In this case, the first opening 422 and the first gas holes 411 may be disposed at positions which do not overlap, or only some thereof may be disposed at positions which overlap.

Moreover, the second openings 423 may be respectively disposed vertically under the second gas holes 412. In this case, the second opening 423 and the second gas holes 412 may be disposed on the same vertical line. Although not shown, the second opening 423 and the second gas holes 412 may be disposed at staggered positions. In this case, the second opening 423 and the second gas holes 412 may be disposed at positions which do not overlap, or only some thereof may be disposed at positions which overlap.

Furthermore, the injection unit 4 may generate plasma by using the second plate 42 and the first plate 41. In this case, a plasma power such as radio frequency (RF) power may be applied to the first plate 41, and the second plate 42 may be grounded. The first plate 41 may be grounded, and the plasma power may be applied to the second plate 42.

The ferroelectric capacitor 200 according to the present invention may be manufactured through a processing process using the substrate processing apparatus 1. The ferroelectric capacitor 200 according to the present invention may include a first electrode 220 and a ferroelectric layer 230.

Referring to FIGS. 1 to 4, the first electrode 220 is formed on the substrate 210. The first electrode 220 may include titanium nitride (TiN). The first electrode 220 may be disposed between the substrate 210 and the ferroelectric layer 230. In the ferroelectric capacitor 200 according to the present invention, the first electrode 220 may function as a lower electrode. The first electrode 220 may be manufactured by using the substrate processing apparatus 1. In this case, a source gas including titanium may be injected through the first gas flow path 4a. A reactant gas including nitrogen may be injected through the second gas flow path 4b.

Referring to FIGS. 1 to 4, the ferroelectric layer 230 is formed on the first electrode 220. The ferroelectric layer 230 may be manufactured by using ferroelectrics having ferroelectricity. The ferroelectric layer 230 may include hafnium (Hf) oxide. In this case, a source gas including hafnium may be injected through the first gas flow path 4a. A reactant gas including oxygen may be injected through the second gas flow path 4b. Accordingly, the ferroelectric layer 230 may be formed by an atomic layer deposition (ALD) process.

The ferroelectric layer 230 may include hafnium and zirconium. When the ferroelectric layer 230 includes hafnium and zirconium, the ferroelectric layer 230 may be formed to include hafnium zirconium oxide (HZO). Accordingly, in the ferroelectric capacitor 200 according to the present invention, the film quality of the ferroelectric layer 230 may be enhanced by using hafnium zirconium oxide. Hafnium and zirconium (Zr) may be simultaneously supplied to the first electrode 220, and thus, the ferroelectric layer 230 may be formed. In this case, comparing with a comparative example where the ferroelectric layer 230 is formed by sequentially supplying hafnium and zirconium, in the ferroelectric capacitor 200 according to the present invention, the ferroelectric layer 230 may be formed by simultaneously supplying hafnium and zirconium, thereby contributing to shortening a process time for forming the ferroelectric layer 230. In this case, a source gas where hafnium and zirconium are mixed may be injected through the first gas flow path 4a. That is, hafnium and zirconium may be supplied by a co-flow process. A reactant gas including oxygen may be injected through the second gas flow path 4b. Therefore, the ferroelectric layer 230 including hafnium zirconium oxide may be formed by an atomic layer deposition (ALD) process.

The ferroelectric layer 230 may be formed on the first electrode 220, and then, may be annealed by a gas including nitrogen and thus may be implemented. The ferroelectric layer 230 may be crystallized through annealing, and thus, the ferroelectric capacitor 200 according to the present invention may be implemented to include the ferroelectric layer 230 having film quality which is more enhanced. When the ferroelectric layer 230 includes hafnium zirconium oxide, hafnium zirconium oxide may be crystallized through annealing. Also, the ferroelectric layer 230 may be implemented by performing a post metallization annealing (PMA) process for 10 sec to 20 sec at an atmosphere of 500 °C to 550 °C, based on a gas including nitrogen.

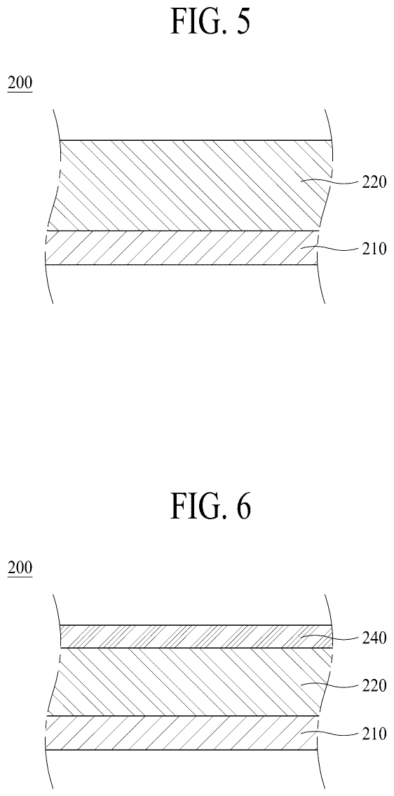

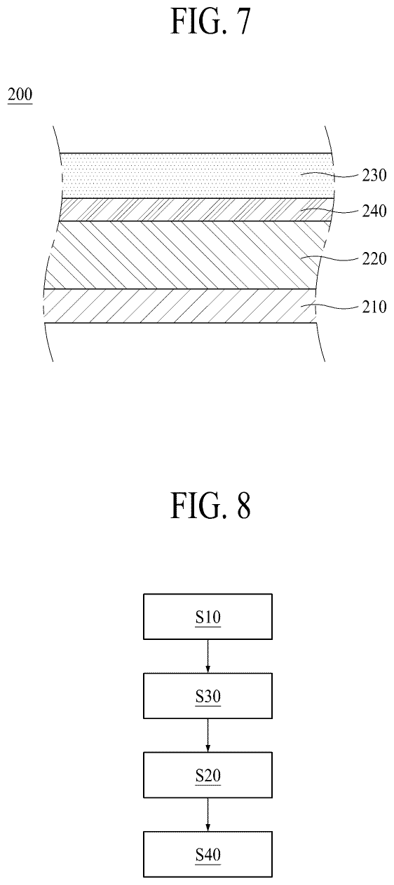

Referring to FIGS. 1 to 7, the ferroelectric capacitor 200 according to the present invention may further include an interface layer 240.

The interface layer 240 is disposed between the ferroelectric layer 230 and the first electrode 220. The interface layer 240 may be formed on the first electrode 220. In this case, the ferroelectric layer 230 may be formed on the interface layer 240.

The interface layer 240 may include titanium oxide. Therefore, by using an oxygen scavenging effect of titanium oxide, the interface layer 240 may prevent an oxygen vacancy from being formed in a process of forming the ferroelectric layer 230. Accordingly, the interface layer 240 may more reinforce the ferroelectricity of the ferroelectric layer 230. Also, the ferroelectric capacitor 200 according to the present invention may increase a residual polarization value of the ferroelectric layer 230, and thus, may be implemented to enable driving with a lower voltage. The interface layer 240 may prevent the formation of an oxygen vacancy when a process of annealing the ferroelectric layer 230 is performed or at an initial step of growing the ferroelectric layer 230 through an atomic layer deposition (ALD) process.

Treatment on the first electrode 220 may be performed with ozone (O₃), and thus, the first interface layer 240 may be implemented. In this case, the interface layer 240 may include titanium dioxide (TiO₂). As treatment on the first electrode 220 including titanium nitride is performed with ozone, TiNxOy and a titanium dioxide thin film may be formed on the first electrode 220, and an oxygen vacancy having a low concentration may be formed by a high ozone concentration based on treatment performed with ozone. Therefore, when a concentration of an oxygen vacancy is high, an oxygen vacancy having a high concentration may hinder the stabilization of ferroelectrics in a process of forming the ferroelectric layer 230, and thus, may prevent the ferroelectricity of the ferroelectric layer 230 from being weakened. Accordingly, an oxygen vacancy having a low concentration based on treatment performed with ozone may induce the stable initial growth of ferroelectrics, and thus, may reinforce the ferroelectrics of the ferroelectric layer 230. In this case, comparing with a comparative example where the interface layer 240 including titanium dioxide (TiO₂) is formed on the first electrode 220 through deposition, in an embodiment, as treatment on the first electrode 220 is performed with ozone, an oxygen vacancy having a low concentration may be obtained by a high ozone concentration at a growth initial step, and thus, ferroelectricity may be more reinforced based on the more stable growth of ferroelectrics. A process of performing treatment on the first electrode 220 with ozone may be performed by performing ozone injection and plasma formation by using the injection unit 4 of the substrate processing apparatus 1.

The interface layer 240 may be implemented by performing treatment on the first electrode 220 with oxygen (O₂). In this case, the interface layer 240 may include titanium dioxide (TiO₂). As treatment on the first electrode 220 including titanium nitride is performed with oxygen, TiNxOy and a titanium dioxide thin film may be formed on the first electrode 220, and an oxygen vacancy having a low concentration may be formed by a high ozone concentration based on treatment performed with oxygen. Therefore, when a concentration of an oxygen vacancy is high, an oxygen vacancy having a high concentration may hinder the stabilization of ferroelectrics in a process of forming the ferroelectric layer 230, and thus, may prevent the ferroelectricity of the ferroelectric layer 230 from being weakened. Accordingly, an oxygen vacancy having a low concentration based on treatment performed with oxygen may induce the stable initial growth of ferroelectrics, and thus, may reinforce the ferroelectrics of the ferroelectric layer 230. In this case, comparing with a comparative example where the interface layer 240 including titanium dioxide (TiO₂) is formed on the first electrode 220 through deposition, in an embodiment, as treatment on the first electrode 220 is performed with oxygen, an oxygen vacancy having a low concentration may be obtained by a high ozone concentration at a growth initial step, and thus, ferroelectricity may be more reinforced based on the more stable growth of ferroelectrics. A process of performing treatment on the first electrode 220 with oxygen may be performed by performing oxygen injection and plasma formation by using the injection unit 4 of the substrate processing apparatus 1.

Treatment on the interface layer 240 may be performed with oxygen (O₂) plasma. Therefore, in the ferroelectric capacitor 200 according to the present invention, impurities or the like may be removed from the interface layer 240, and thus, the film quality of the interface layer 240 may be enhanced. Also, the ferroelectric layer 230 may be formed on the interface layer 240 after treatment on the interface layer 240 is performed with oxygen plasma, and thus, the ferroelectric capacitor 200 according to the present invention may more enhance the film quality of the ferroelectric layer 230. In this case, oxygen plasma may be formed by the injection unit 4.

The interface layer 240 may be formed to include titanium oxynitride (TiON). Therefore, by using an oxygen scavenging effect of titanium oxynitride, the interface layer 240 may prevent an oxygen vacancy from being formed in a process of forming the ferroelectric layer 230. Accordingly, the interface layer 240 may more reinforce the ferroelectricity of the ferroelectric layer 230. Also, the ferroelectric capacitor 200 according to the present invention may increase a residual polarization value of the ferroelectric layer 230, and thus, may be implemented to enable driving with a lower voltage. The interface layer 240 may prevent the formation of an oxygen vacancy when a process of annealing the ferroelectric layer 230 is performed or at an initial step of growing the ferroelectric layer 230 through an atomic layer deposition (ALD) process.

In a case where the interface layer 240 is formed to include titanium oxynitride, the interface layer 240 may be formed by sequentially injecting a source gas including titanium, a first reactant gas including oxygen, and a second reactant gas including nitrogen. In this case, the source gas including titanium may be injected through the first gas flow path 4a, and the first reactant gas including oxygen and the second reactant gas including nitrogen may be sequentially injected through the second gas flow path 4b. The source gas including titanium may be injected through the first gas flow path 4a, the first reactant gas including oxygen may be injected through the second gas flow path 4b, and the second reactant gas including nitrogen may be injected through a third gas flow path (not shown).

Referring to FIGS. 1 to 7, the ferroelectric capacitor 200 may include a second electrode 250.

The second electrode 250 may be formed on the ferroelectric layer 230. The second electrode 250 may include titanium nitride. In the ferroelectric capacitor 200 according to the present invention, the second electrode 250 may function as an upper electrode. The second electrode 250 and the first electrode 220 may be formed to include different materials.

Hereinafter, an embodiment of a method of manufacturing a ferroelectric capacitor according to the present invention will be described in detail with reference to the accompanying drawings.

Referring to FIGS. 1 to 8, a method of manufacturing a ferroelectric capacitor according to the present invention may be for manufacturing the ferroelectric capacitor 200 according to the present invention described above. The method of manufacturing a ferroelectric capacitor according to the present invention may include the following step.

First, a substrate where a first electrode 220 is formed is prepared (S10). Such a step S10 may be performed by preparing a substrate where the first electrode 220 including titanium nitride is formed. The step S10 of preparing the substrate may be performed as a substrate 210 where the first electrode 220 including titanium nitride is formed is supported by the substrate supporting unit 3 of the substrate processing apparatus 1.

Subsequently, a ferroelectric layer 230 is formed on the first electrode 220 (S20). Such a step S20 may be performed by forming the ferroelectric layer 230 on the first electrode 220 by using ferroelectrics having ferroelectricity. The step S20 of forming the ferroelectric layer may be performed by forming the ferroelectric layer 230 including hafnium oxide. In a case where the step S20 of forming the ferroelectric layer is performed by using the substrate processing apparatus 1, a source gas including hafnium may be injected through the first gas flow path 4a, and then, a reactant gas including oxygen may be injected through the second gas flow path 4b, whereby the ferroelectric layer 230 may be formed. In this case, the ferroelectric layer 230 may be formed by an atomic layer deposition (ALD) process.

The step S20 of forming the ferroelectric layer may form a ferroelectric layer 230 which further includes zirconium. The step S20 of forming the ferroelectric layer may be performed by forming the ferroelectric layer 230 including hafnium zirconium oxide on the first electrode 220. Therefore, the method of manufacturing a ferroelectric capacitor according to the present invention may enhance the film quality of the ferroelectric layer 230 by using hafnium zirconium oxide. The step S20 of forming the ferroelectric layer may simultaneously supply hafnium and zirconium to the first electrode 220 to form the ferroelectric layer 230 including hafnium zirconium oxide on the first electrode 220. In this case, comparing with a comparative example which sequentially supplies hafnium and zirconium to form the ferroelectric layer 230, the method of manufacturing a ferroelectric capacitor according to the present invention may simultaneously supply hafnium and zirconium to form the ferroelectric layer 230, and thus, may shorten a process time for forming the ferroelectric layer 230. Therefore, the method of manufacturing a ferroelectric capacitor according to the present invention may contribute to increasing the production of the ferroelectric capacitor 200. In a case where the step S20 of forming the ferroelectric layer is performed by using the substrate processing apparatus 1, a source gas where hafnium and zirconium are mixed may be injected through the first gas flow path 4a. That is, hafnium and zirconium may be supplied by a co-flow process. Also, after the source gas where hafnium and zirconium are mixed is injected through the first gas flow path 4a, a reactant gas including oxygen may be injected through the second gas flow path 4b. Accordingly, the ferroelectric layer 230 including hafnium zirconium oxide may be formed by an atomic layer deposition (ALD) process.

Referring to FIGS. 1 to 8, the method of manufacturing a ferroelectric capacitor according to the present invention may further include a step S30 of forming an interface layer.

The step S30 of forming the interface layer may be performed by forming an interface layer 240 including titanium oxide on the first electrode 220. After the step S30 of forming the interface layer is performed, the step S20 of forming the ferroelectric layer may be performed. Therefore, the method of manufacturing a ferroelectric capacitor according to the present invention may prevent the formation of an oxygen vacancy in the ferroelectric layer 230 in the step S20 of forming the ferroelectric layer by using an oxygen scavenging effect of titanium oxide formed through the step S30 of forming the interface layer. Accordingly, the method of manufacturing a ferroelectric capacitor according to the present invention may more reinforce the ferroelectricity of the ferroelectric layer 230. Also, the method of manufacturing a ferroelectric capacitor according to the present invention may increase a residual polarization value of the ferroelectric layer 230, and thus, may manufacture the ferroelectric capacitor 200 where driving is possible with a lower voltage.

The step S30 of forming the interface layer may be performed by performing treatment on the first electrode 220 with ozone to form an interface layer including titanium oxide on the first electrode 220. Therefore, in the step S30 of forming the interface layer, an oxygen vacancy having a low concentration based on treatment performed with ozone may induce the stable initial growth of ferroelectrics, and thus, may reinforce the ferroelectrics of the ferroelectric layer 230. The step S30 of forming the interface layer may be performed by forming an interface layer 240 including titanium dioxide. In this case, comparing with a comparative example which forms the interface layer 240 including titanium dioxide (TiO₂) on the first electrode 220 through deposition, in the step S30 of forming the interface layer, as treatment is performed with ozone, an oxygen vacancy having a low concentration may be obtained by a high ozone concentration at a growth initial step, and thus, ferroelectricity may be more reinforced based on the more stable growth of ferroelectrics.

The step S30 of forming the interface layer may be performed by performing treatment on the first electrode 220 with oxygen to form an interface layer including titanium oxide on the first electrode 220. Therefore, in the step S30 of forming the interface layer, an oxygen vacancy having a low concentration based on treatment performed with oxygen may induce the stable initial growth of ferroelectrics, and thus, may reinforce the ferroelectrics of the ferroelectric layer 230. The step S30 of forming the interface layer may be performed by forming the interface layer 240 including titanium dioxide. In this case, comparing with a comparative example which forms the interface layer 240 including titanium dioxide (TiO₂) on the first electrode 220 through deposition, in the step S30 of forming the interface layer, as treatment is performed with oxygen, an oxygen vacancy having a low concentration may be obtained by a high oxygen concentration at a growth initial step, and thus, ferroelectricity may be more reinforced based on the more stable growth of ferroelectrics.

Referring to FIGS. 1 to 8, the method of manufacturing a ferroelectric capacitor according to the present invention may further include an annealing step S40.

The annealing step S40 may be performed after the step of forming the ferroelectric layer is performed. The annealing step S40 may be performed by annealing the ferroelectric layer 230 with a gas including nitrogen. Therefore, the annealing step S40 may crystallize the ferroelectric layer 230, and thus, may more enhance the film quality of the ferroelectric layer 230. When the ferroelectric layer 230 includes hafnium zirconium oxide, hafnium zirconium oxide may be crystallized through annealing. Also, the annealing step S40 may be implemented by performing a post metallization annealing (PMA) process for 10 sec to 20 sec at an atmosphere of 500 °C to 550 °C, based on a gas including nitrogen.

Although not shown, the method of manufacturing a ferroelectric capacitor according to the present invention may further include a step of forming a second electrode.

The step of forming the second electrode may be performed by forming the second electrode 250 on the ferroelectric layer 230. The second electrode 250 may include titanium nitride. The step of forming the second electrode may be performed by forming the second electrode with a material which differs from that of the first electrode 220.

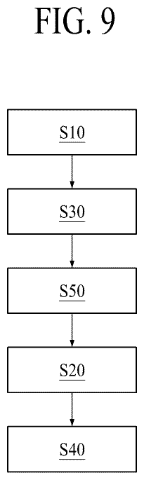

Referring to FIGS. 1 to 9, the method of manufacturing a ferroelectric capacitor according to the present invention may include a step S50 of performing treatment on an interface layer with oxygen plasma.

The step S50 of performing treatment on the interface layer with oxygen plasma may be performed after the step S30 of forming the interface layer. After the step S50 of performing treatment on the interface layer with oxygen plasma is performed, the step S20 of forming the ferroelectric layer may be performed.

The step S50 of performing treatment on the interface layer with oxygen plasma may be performed by performing treatment on the interface layer 240 with oxygen plasma. Therefore, the method of manufacturing a ferroelectric capacitor according to the present invention may remove impurities from the interface layer 240, and thus, may enhance the film quality of the interface layer 240. Also, the method of manufacturing a ferroelectric capacitor according to the present invention may form the ferroelectric layer 230 on the interface layer 240 on which treatment has been performed with oxygen plasma, and thus, may form the ferroelectric layer 230 having film quality which is more enhanced. The step S50 of performing treatment on the interface layer with oxygen plasma may be performed by forming oxygen plasma by using the injection unit 4. In this case, the injection unit 4 may form plasma by using the first plate 41 and the second plate 42 and may inject oxygen through at least one of the first gas flow path 4a and the second gas flow path 4b.

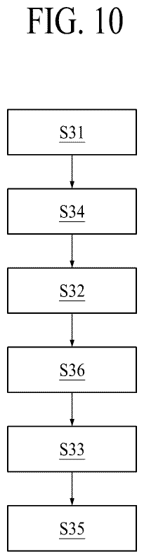

Referring to FIGS. 1 to 10, in the method of manufacturing a ferroelectric capacitor according to the present invention, the step S30 of forming the interface layer may be performed by forming an interface layer 240 including titanium oxynitride (TiON). Therefore, the method of manufacturing a ferroelectric capacitor according to the present invention may prevent the formation of an oxygen vacancy in the ferroelectric layer 230 in the step S20 of forming the ferroelectric layer by using an oxygen scavenging effect of titanium oxynitride formed through the step S30 of forming the interface layer. Accordingly, the method of manufacturing a ferroelectric capacitor according to the present invention may more reinforce the ferroelectricity of the ferroelectric layer 230. Also, the method of manufacturing a ferroelectric capacitor according to the present invention may increase a residual polarization value of the ferroelectric layer 230, and thus, may manufacture the ferroelectric capacitor 200 where driving is possible with a lower voltage.

The step S30 of forming the interface layer may include a step S31 of injecting a source gas, a step S32 of injecting a first reactant gas, and a step S33 of injecting a second reactant gas.

The step S31 of injecting the source gas may be performed by injecting a source gas including titanium. Such a step S31 may be performed by injecting the source gas including titanium toward the substrate 210 by using the injection unit 4. The source gas including titanium may be injected through the first gas flow path 4a. An adsorption process of adsorbing titanium may be performed through the step S31 of injecting the source gas.

The step S32 of injecting the first reactant gas may be performed by injecting a first reactant gas including oxygen. Such a step S32 may be performed by injecting the first reactant gas including oxygen toward the substrate 210 by using the injection unit 4. The first reactant gas including oxygen may be injected through the second gas flow path 4b.

The step S33 of injecting the second reactant gas may be performed by injecting a second reactant gas including nitrogen. Such a step S33 may be performed by injecting the second reactant gas including nitrogen toward the substrate 210 by using the injection unit 4. The second reactant gas including nitrogen may be injected through the second gas flow path 4b. The second reactant gas including nitrogen may also be injected through the third gas flow path. A deposition process where the interface layer 240 including titanium oxynitride is deposited as the first reactant gas including oxygen and the second reactant gas including nitrogen react titanium adsorbed by the adsorption process may be performed through the step S32 of injecting the first reactant gas and the step S33 of injecting the second reactant gas. In this case, the interface layer 240 may be formed by an atomic layer deposition process.

The step S30 of forming the interface layer may include a step S34 of injecting a first purge gas and a step S35 of injecting a second purge gas.

The step S34 of injecting the first purge gas may be performed by injecting the first purge gas by using the injection unit 4. The first purge gas may be injected into the processing space 100 through at least one of the first gas flow path 4a and the second gas flow path 4b. The first purge gas may be injected into the processing space 100 through at least one of the first gas flow path 4a, the second gas flow path 4b, and the third gas flow path. The first purge gas may be an inert gas such as argon (Ar). The step S34 of injecting the first purge gas may be performed after the step S31 of injecting the source gas is performed. Therefore, a purge process of purging titanium, which is not used in the adsorption process, from the processing space 100 may be performed through the step S34 of injecting the first purge gas. After the step S34 of injecting the first purge gas is performed, the step S32 of injecting the first reactant gas may be performed.

The step S35 of injecting the second purge gas may be performed by injecting the second purge gas by using the injection unit 4. The second purge gas may be injected into the processing space 100 through at least one of the first gas flow path 4a and the second gas flow path 4b. The second purge gas may be injected into the processing space 100 through at least one of the first gas flow path 4a, the second gas flow path 4b, and the third gas flow path. The first purge gas may be an inert gas such as argon. The step S35 of injecting the second purge gas may be performed after the step S33 of injecting the second reactant gas is performed. Therefore, a purge process of purging titanium, which is not used in the deposition process, from the processing space 100 may be performed through the step S33 of injecting the second purge gas. After the step S35 of injecting the second purge gas is performed, the step S20 of forming the ferroelectric layer or the step S50 of performing treatment on the interface layer with oxygen plasma may be performed.

The step S30 of forming the interface layer may include a step S36 of injecting a third purge gas.

The step S36 of injecting the third purge gas may be performed by injecting the third purge gas by using the injection unit 4. The third purge gas may be injected into the processing space 100 through at least one of the first gas flow path 4a and the second gas flow path 4b. The third purge gas may be injected into the processing space 100 through at least one of the first gas flow path 4a, the second gas flow path 4b, and the third gas flow path. The third purge gas may be an inert gas such as argon. The step S36 of injecting the third purge gas may be performed after the step S32 of injecting the first reactant gas is performed. Therefore, a purge process of purging titanium, which is not used in the deposition process, from the processing space 100 may be performed through the step S36 of injecting the third purge gas. After the step S36 of injecting the third purge gas is performed, the step S33 of injecting the second reactant gas may be performed.

The present invention described above are not limited to the above-described embodiments and the accompanying drawings and those skilled in the art will clearly appreciate that various modifications, deformations, and substitutions are possible without departing from the scope and spirit of the invention.

1. A method of manufacturing a ferroelectric capacitor, the method comprising:
a step of preparing a substrate where a first electrode including titanium nitride (TiN) is formed;
a step of performing treatment on the first electrode with ozone (O₃) or oxygen (O₂) to form an interface layer including titanium oxide on the first electrode; and
a step of forming a ferroelectric layer including hafnium (Hf) oxide or hafnium zirconium oxide (HZO) on the interface layer.

2. The method of manufacturing a ferroelectric capacitor of claim 1, wherein, in a case which forms the ferroelectric layer including hafnium oxide, the step of forming the ferroelectric layer forms the ferroelectric layer further including zirconium (Zr).

3. The method of manufacturing a ferroelectric capacitor of claim 1, wherein, in a case which forms the ferroelectric layer including the hafnium zirconium oxide, the step of forming the ferroelectric layer simultaneously supplies hafnium and zirconium to the interface layer to form the ferroelectric layer including the hafnium zirconium oxide on the interface layer.

4. The method of manufacturing a ferroelectric capacitor of claim 1, further comprising a step of annealing with a gas including nitrogen after the ferroelectric layer is formed.

5. The method of manufacturing a ferroelectric capacitor of claim 1, wherein the step of forming the interface layer forms the interface layer including titanium dioxide (TiO₂).

6. The method of manufacturing a ferroelectric capacitor of claim 1, further comprising a step of performing treatment on the interface layer with oxygen plasma,
wherein the step of forming the ferroelectric layer is performed after the step of performing the treatment with the oxygen plasma is performed.

7. A method of manufacturing a ferroelectric capacitor, the method comprising:
a step of preparing a substrate where a first electrode including titanium nitride (TiN) is formed;
a step of forming an interface layer including titanium oxynitride (TiON) on the first electrode; and
a step of forming a ferroelectric layer including hafnium (Hf) oxide or hafnium zirconium oxide (HZO) on the interface layer.

8. The method of manufacturing a ferroelectric capacitor of claim 7, wherein the step of forming the interface layer comprises:
a step of injecting a source gas including titanium;
a step of injecting a first reactant gas including oxygen; and
a step of injecting a second reactant gas including nitrogen.

9. A ferroelectric capacitor:
a first electrode including titanium nitride (TiN);
a ferroelectric layer formed on the first electrode, the ferroelectric layer including hafnium (Hf) oxide or hafnium zirconium oxide (HZO); and
an interface layer disposed between the ferroelectric layer and the first electrode,
wherein the interface layer comprises titanium oxide or titanium oxynitride (TiON).

10. The ferroelectric capacitor of claim 12, wherein the interface layer comprises titanium dioxide (TiO₂).

11. The ferroelectric capacitor of claim 9,
wherein the interface layer comprises titanium oxynitride (TiON).

12. The ferroelectric capacitor of claim 9, wherein the interface layer comprises titanium oxide and is formed by performing treatment on the first electrode with ozone (O3) or oxygen (O2).
